(19) United States
(12) Patent Application Publication
(10) Pub. No.: US 2026/0075835 A1
(43) Pub. Date: Mar. 12, 2026

(54) ELECTRONIC DEVICE INCLUDING FERROELECTRIC AND METHOD OF MANUFACTURING THE ELECTRONIC DEVICE

(71) Applicant: Samsung Electronics Co., Ltd., Suwon-si (KR)

(72) Inventors: Donghyun KIM, Suwon-si (KR); Kyooho JUNG, Suwon-si (KR); Jooho LEE, Suwon-si (KR); Dukhyun CHOE, Suwon-si (KR)

(73) Assignee: Samsung Electronics Co., Ltd., Suwon-si (KR)

(21) Appl. No.: 19/024,590

(22) Filed: Jan. 16, 2025

(30) Foreign Application Priority Data
Sep. 9, 2024 (KR) 10-2024-0122581

(51) Int. Cl. H10B 53/30; H10D 1/68; H10D 30/69

(52) U.S. Cl. CPC H10B 53/30; H10D 1/68; H10D 30/701

(57) ABSTRACT

An electronic device includes a lower electrode, a ferroelectric layer disposed on the lower electrode, and an upper electrode disposed on the ferroelectric layer. The ferroelectric layer comprises a crystalline structure of an orthorhombic phase, and a metal oxide including Hf and Zr and a metal oxide including Co or Nb.

### CROSS-REFERENCE TO RELATED APPLICATION

This application is based on and claims priority under 35 U.S.C. § 119 to Korean Patent Application No. 10-2024-0122581, filed on Sep. 9, 2024, in the Korean Intellectual Property Office, the disclosure of which is incorporated by reference herein in its entirety.

### BACKGROUND

### 1. Field

The disclosure relates to an electronic device including a ferroelectric and a method of manufacturing the electronic device.

### 2. Description of the Related Art

As the down-scaling of electronic apparatuses is progressing, the space occupied by electronic circuits in electronic apparatuses is also decreasing. Thus, demand for the miniaturization and high performance of electronic devices such as capacitors, transistors, etc., included in electronic circuits is also increasing.

Hafnium zirconium oxide (HZO) has attracted attention for use in a dielectric layer in such electronic devices. Due to the spatial limitation according to down-scaling, there is a need to better exhibit ferroelectric properties such as remnant polarization, etc., even at small thicknesses.

### SUMMARY

Provided are an electronic device including a ferroelectric and a method of manufacturing the electronic device.

Additional aspects will be set forth in part in the description which follows and, in part, will be apparent from the description, or may be learned by practice of the presented embodiments of the present disclosure.

According to an aspect of the disclosure, an electronic device includes a lower electrode; an upper electrode; and a ferroelectric layer separating the lower electrode and the upper electrode, the ferroelectric layer including a crystalline structure of an orthorhombic phase comprising a metal oxide including Hf and Zr and a metal oxide including at least one of Co or Nb.

The ferroelectric layer may further include a crystalline structure of a tetragonal phase.

In the ferroelectric layer, a content of Hf may be greater than a content of Zr.

A thickness of the ferroelectric layer may be at least about 1 nm and about 7 nm or less.

The upper electrode may include TiN, W, Mo, or Ni.

The electronic device may further include an interfacial layer between the lower electrode and the ferroelectric layer, the interfacial layer including a metal oxide.

A thickness of the interfacial layer may be not more than about 1 nm.

The interfacial layer may include a metal oxide including at least one of Hf, Zr, Al, Ti, Ta, or Nb.

According to another aspect of the disclosure, an electronic device includes a transistor and one or more capacitors electrically connected to the transistor, in which the one or more capacitors includes a lower electrode; an upper electrode ; and a ferroelectric layer separating the lower electrode and the upper electrode, the ferroelectric layer including a crystalline structure of an orthorhombic phase comprising a metal oxide including Hf and Zr and a metal oxide including at least one of Co or Nb.

According to another aspect of the disclosure, an electronic device includes a semiconductor substrate; a gate electrode; and a ferroelectric layer separating the gate electrode and the semiconductor substrate, in which the ferroelectric layer including a crystalline structure of an orthorhombic phase and including a metal oxide including Hf and Zr and a metal oxide including at least one of Co or Nb.

According to another aspect of the disclosure, a method of manufacturing an electronic device includes forming a dielectric layer including a metal oxide including Hf and Zr, forming a crystalline induction electrode on the dielectric layer, forming a ferroelectric layer by annealing the dielectric layer and the crystalline induction electrode such that the metal oxide crystallizes, removing the crystalline induction electrode, and forming an upper electrode on the ferroelectric layer.

The forming the ferroelectric layer may include forming a crystalline structure of an orthorhombic phase in the metal oxide of the ferroelectric layer.

The crystalline induction electrode may include at least one of Co, CoN, NbN, or Nb.

The ferroelectric layer, after removing the crystalline induction electrode, may further include a metal oxide including Co or Nb.

A temperature during the annealing may be about 500° C. or less.

A content of Hf may be greater than a content of Zr in the ferroelectric layer.

A thickness of the ferroelectric layer may be at least about 1 nm and about 7 nm or less.

The upper electrode may include TiN, W, Mo, or Ni.

The forming the dielectric may include forming the dielectric layer on a lower electrode.

The forming the dielectric may include forming the dielectric layer on a semiconductor substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a schematic configuration of an electronic device according to at least one embodiment;

FIGS. 2A to 2F are views for describing a method of manufacturing an electronic device according to at least one embodiment;

FIG. 3 is a graph comparatively showing P-V curves of an electronic device according to at least one embodiment and an electronic device according to a comparison example;

FIG. 4 is an x-ray diffraction (XRD) graph of a ferroelectric layer included in an electronic device manufactured by a method according to at least one embodiment;

FIG. 5 is a cross-sectional view showing a schematic configuration of an electronic device according to at least one embodiment;

FIG. 6 is a schematic circuit diagram of an electronic device according to at least one embodiment;

FIG. 7 is a schematic cross-sectional view of an electronic device according to at least one embodiment;

FIG. 8 is a schematic cross-sectional view of an electronic device according to at least one embodiment;

FIG. 9 is a schematic cross-sectional view of an electronic device according to at least one embodiment; and

FIGS. 10 and 11 are conceptual views schematically showing a device architecture applicable to an apparatus according to an example embodiment.

### DETAILED DESCRIPTION

Reference will now be made in detail to embodiments, examples of which are illustrated in the accompanying drawings, wherein like reference numerals refer to like elements throughout. In this regard, the current embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, at least one embodiment will be described in detail with reference to the accompanying drawings. Embodiments to be described are merely examples, and various modifications may be made from such embodiments. In the drawings, like reference numerals denote like components, and sizes of components in the drawings may be exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

An expression such as “above” or “on” may include not only the meaning of “immediately on in a contact manner”, but also the meaning of “on in a non-contact manner”. Additionally, spatially relative terms, such as “above”, “below”, and/or similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

Although the terms “first,” “second,” etc., may be used herein to describe various components, these terms are used to distinguish one component from other components. These terms do not limit that materials or structures of components are different from one another.

Singular forms may include plural forms unless apparently indicated otherwise contextually. When a portion is referred to as “comprises” a component, the portion may not exclude another component but may further include another component unless stated otherwise.

Terms used herein, such as “unit” or “module”, indicating a unit for processing of at least one function or operation may be implemented in processing circuitry, such as hardware, software, and/or in a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components (such as at least one of transistors, resistors, capacitors, etc.), and/or electronic circuits including said components.

The use of the terms of “the above-described” and similar indicative terms may correspond to both the singular forms and the plural forms.

Also, operations constituting a method may be performed in any suitable order unless it is explicitly stated that they should be performed in an order they are described. Also, the use of all exemplary terms (for example, etc.) is only to describe technical spirit in detail, and the scope of rights is not limited by these terms unless limited by the claims.

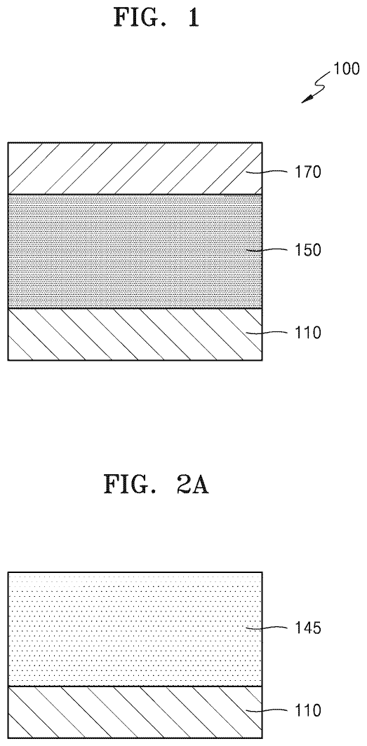

FIG. 1 is a cross-sectional view showing a schematic configuration of an electronic device according to at least one embodiment.

An electronic device 100 according to at least one embodiment includes a lower electrode 110, a ferroelectric layer 150 disposed on the lower electrode 110, and an upper electrode 170 disposed on the ferroelectric layer 150. The electronic device 100 may be a capacitor. The electronic device 100 may be referred to as a ferroelectric capacitor in comparison to a comparative capacitor including a paraelectric.

The lower electrode 110 may include a conductive (e.g., a zero-bandgap) material. The lower electrode 110 may include, for example, a metal, a metal oxide, a metal nitride, and/or a combination thereof. The lower electrode 110 may include, for example, a metal material including at least one of beryllium (Be), boron (B), sodium (Na), magnesium (Mg), aluminum (Al), silicon (Si), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), tellurium (Te), cesium (Cs), barium (Ba), lanthanum (La), cerium (Ce), praseodymium (Pr), neodymium (Nd), promethium (Pm), samarium (Sm), europium (Eu), gadolinium (Gd), terbium (Tb), dysprosium (Dy), Ho, erbium (Er), thulium (Tm), ytterbium (Yb), lutetium (Lu), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), francium (Fr), radium (Ra), actinium (Ac), thorium (Th), protactinium (Pa), or uranium (U), and/or an oxide and/or a nitride of any one of them.

The ferroelectric layer 150 may include a metal oxide including Hf and Zr. The ferroelectric layer 150 may include, for example, HfₓZr₍₁₋ₓ₎O (x is a real number greater than 0 and less than 1). Hereinbelow, HfₓZr₍₁₋ₓ₎O may be simply referred to as HZO. The ferroelectric layer 150 may include a crystalline structure with an orthorhombic phase. The ferroelectric layer 150 may further have a tetragonal phase. For example, HZO included in the ferroelectric layer 150 may have a crystalline structure grown preferentially in the orthorhombic phase. Therefore, the ferroelectric layer 150 may also be referred to as having a crystalline structure with the orthorhombic phase as the primary or dominant phase. HZO may have a structure crystalized in the tetragonal phase and the orthorhombic phase, and the crystalized structure may include the orthorhombic phase more than the tetragonal phase. In other words, the ferroelectric layer 150 may include various crystalline phases such as an orthorhombic crystalline phase, a tetragonal crystalline phase, etc., but may include the orthorhombic crystalline phase as a dominant phase or at the greatest proportion among all crystalline phases.

Herein, the HZO may be referred to as having a structure containing a Zr-doped hafnium oxide (HfO₂), and exhibiting para-electricity, ferro-electricity, or anti-ferroelectricity and have different remnant polarization or hysteresis characteristics, according to the amount of Zr and/or a stress state with an adjacent layer.

Ferroelectricity refers to a property in which internal electric dipole moments are aligned in a material to maintain a spontaneous polarization without any external electric field applied thereto. Even when a specific voltage is applied to a substance having such a property, i.e., ferroelectrics, and then the voltage is brought back to 0 V, polarization in the ferroelectrics may remain semi-permanently. Ferroelectricity may be phase dependent, such that a material having a ferroelectric phase (e.g., a crystal structure lacking an inversion center (e.g., is non-centrosymmetric) as a dominant phase exhibits ferroelectricity, while a comparative material including the same (or similar composition) but lacking the ferroelectric phase may lack ferroelectricity.

Therefore, the HZO included in the ferroelectric layer 150 of the electronic device 100 according to at least one embodiment may include an orthorhombic phase dominantly, have ferroelectricity exhibited well, and have a high remnant polarization property.

In at least some embodiments, the ferroelectric layer 150 may be doped with Y, Al, Ti, Sr, La, and/or nitrogen (N). In other words, the ferroelectric layer 150 may have a structure with a Zr-doped HfO₂ further doped with a dopant other than Zr. The ferroelectric layer 150 may include, for example, HfO_{y}, ZrO_{y}, and at least one of AlO_{y}, TiO_{y}, TaO_{y}, and/or NbO_{y} in which y is a real number greater than 0.

In HfₓZr₍₁₋ₓ₎O included in the ferroelectric layer 150, x may be greater than 0.5. In other words, the ferroelectric layer 150 may have a content of Hf greater than a content of Zr.

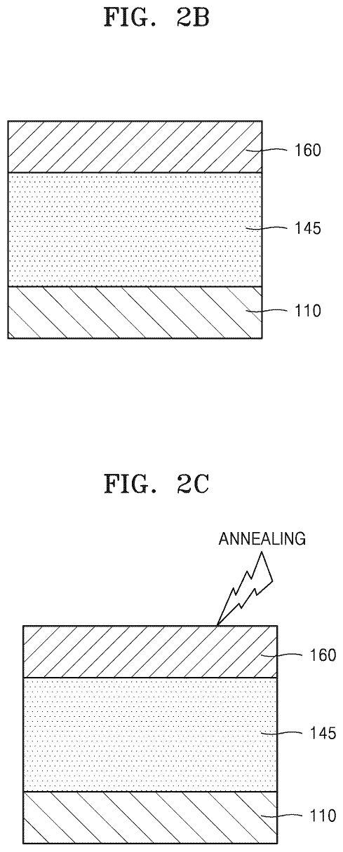

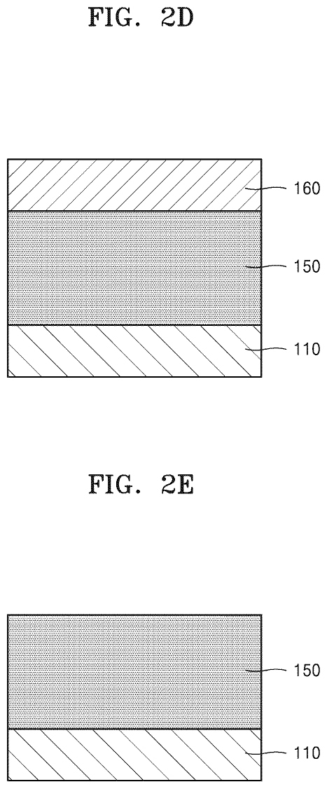

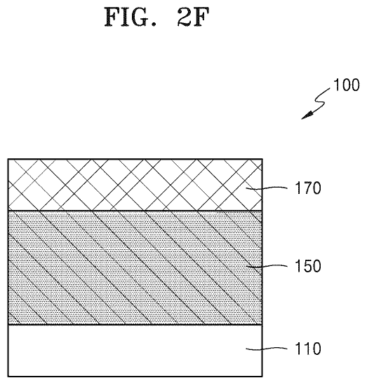

The ferroelectric layer 150 may further include a metal element other than Hf and Zr. The ferroelectric layer 150 may include a metal oxide including a metal element. The ferroelectric layer 150 may include a metal oxide including, for example, Co or Nb. Such a metal element may be an impurity that is a result of a manufacturing method for crystallizing the ferroelectric layer 150. The manufacturing method will be described with reference to FIGS. 2A to 2F.

A thickness of the ferroelectric layer 150 may be less than or equal to about 10 nanometers (nm) and/or less than or equal to about 7 nm. The thickness of the ferroelectric layer 150 may be, for example, at least about 1 nm and about 7 nm or less.

The upper electrode 170 may include a conductive (e.g., a zero-bandgap) material. The upper electrode 170 may include, for example, metal, a metal oxide, a metal nitride, or a combination thereof. The upper electrode 170 may include, for example, TiN, W, Mo, or Ni.

A material of the upper electrode 170 may be the same as or different from a material of the lower electrode 110.

FIGS. 2A to 2F are views for describing a method of manufacturing an electronic device according to at least one embodiment.

Referring to FIG. 2A, a dielectric layer 145 may be formed on the lower electrode 110.

The dielectric layer 145 may include a metal oxide including Hf and Zr. The dielectric layer 145 may include HZO. To form the dielectric layer 145, a deposition method such as atomic layer deposition (ALD)), metal organic atomic layer deposition (MOALD), chemical vapor deposition (CVD), metal organic chemical vapor deposition (MOCVD), physical vapor deposition (PVD), sputtering, etc., may be used.

When the dielectric layer 145 is formed using ALD, a precursors may be used as a hafnium source, a zirconium source, and an oxygen source, respectively. For example, as the hafnium source at least one of hafnium(IV) tert-butoxide Hf(O-t-Bu)₄, tetrakis ethyl methyl amino hafnium (TEMAH), tetrakis di-methyl amino hafnium (TDMAH), tetrakis di-ethyl amino hafnium (TDEAH), and/or a combination thereof may be used, but the disclosure is not limited thereto. As the zirconium source at least one of Zr(O-t-Bu)₄, tetrakis ethyl methyl amino zirconium (TEMAZ), tetrakis di-methyl amino zirconium (TDMAZ), tetrakis di-ethyl amino zirconium (TDEAH), and/or a combination thereof may be used, but the disclosure is not limited thereto. As the oxygen source at least one of O₃, H₂O, O₂, N₂O, O₂ plasma, and/or a combination thereof may be used, but the disclosure is not limited thereto.

The dielectric layer 145 may be deposited to a thickness of about at least 10 nm or less (e.g., 7 nm) . The dielectric layer 145 formed in this way may be an amorphous layer.

Referring to FIG. 2B, a crystalline induction electrode 160 may be formed on the dielectric layer 145. The crystalline induction electrode 160, which is a metal template, may be used to induce crystallization of the dielectric layer 145 and then removed. In other words, the crystalline induction electrode 160 may include materials selected to induce a ferroelectric phase in the amorphous dielectric layer 145 in, e.g., an annealing process.

The crystalline induction electrode 160 may include, for example, at least one of Co, CoN, NbN, or Nb.

Referring to FIG. 2C, an annealing process may be performed. The dielectric layer 145 in the amorphous state may be crystallized by annealing and form a ferroelectric. An annealing operation may be performed under conditions selected to convert the dielectric layer 145 into a ferroelectric layer 150, including an orthorhombic crystalline phase.

For example, annealing may be performed, but not limited to, at a temperature of about 400° C. to about 1100° C. Annealing may be performed during, but not limited to, at least 1 nano-seconds, 1 micro-seconds, 0.001 seconds, 0.05 seconds, 0.1 seconds, 0.5 seconds, 1 second, 3 seconds, or 5 seconds, but not more than 10 minutes, 5 minutes, 1 minutes, or 30 seconds.

As is known, a higher annealing temperature for crystallization is generally applied for a smaller thickness of HZO. For a thickness of 10 nm, 7 nm, or less, a tetragonal phase is formed well and crystallization to the orthorhombic phase is difficult to achieve. Thereby, over annealing the ferroelectric layer 150 may result in the loss of the ferroelectricity.

In a manufacturing method according to at least one embodiment, annealing may be performed after the crystalline induction electrode 160 is formed on the dielectric layer 145, such that at a relatively low temperature, crystallization of the dielectric layer 145 to the orthorhombic phase may occur. For example, an annealing temperature may be 500° C. or less, and may be about 400° C.

Referring to FIGS. 2D and 2E, the crystallized ferroelectric layer 150 may be formed, and the crystalline induction electrode 160 may be removed by etching, etc.

The ferroelectric layer 150 manufactured in this way may include the orthorhombic phase as the dominant crystalline structure. In at least some embodiments, the ferroelectric layer 150 may further include the tetragonal phase. For example, HZO included in the ferroelectric layer 150 manufactured in this way may have a crystalline structure grown preferentially in the orthorhombic phase. HZO may have a structure crystalized in the tetragonal phase and the orthorhombic phase, and the crystalized structure may include the orthorhombic phase more than the tetragonal phase. In other words, the ferroelectric layer 150 may include various crystalline phases such as an orthorhombic crystalline phase, a tetragonal crystalline phase, etc., but may include the orthorhombic crystalline phase as a dominant phase or at the greatest proportion among all crystalline phases.

A part of the metal element included in the crystalline induction electrode 160 may remain after the crystalline induction electrode 160 is removed, such that the metal element may be included in the ferroelectric layer 150. Thereby, the ferroelectric layer 150 may include a metal oxide including a metal element included in the crystalline induction electrode 160. The metal element may be, for example, Co or Nb. The metal element as the impurity may be Co when the crystalline induction electrode 160 is Co or CoN, and the metal element as the impurity may be Nb when the crystalline induction electrode 160 is Nb or NbN. In at least some embodiments, a concentration of the metal element included in the crystalline induction electrode 160 may be higher at the surface from which the crystalline induction electrode 160 was removed compared to a remainder of the ferroelectric layer 150.

Referring to FIG. 2F, the upper electrode 170 may be formed on the ferroelectric layer 150.

According to the manufacturing method, an electronic device 100 including a ferroelectric may be provided. While the manufactured electronic device 100 is described above as a capacitor including the lower electrode 110, the ferroelectric layer 150, and the upper electrode 170, the disclosure is not limited thereto. Depending on use of the crystallized ferroelectric layer 150, the dielectric layer 145 and the crystalline induction electrode 160 may be formed on various substrates and then annealing may be performed. The substrate may be, for example, a semiconductor substrate, or may be the lower electrode 110 described above, or a structure further including an additional interfacial layer on the lower electrode 110.

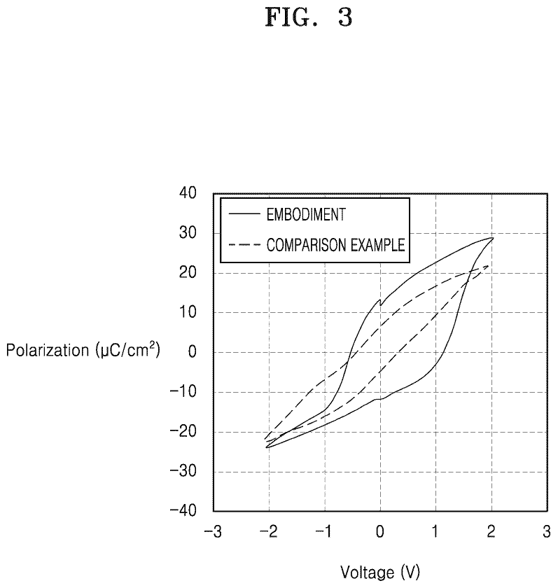

FIG. 3 is a graph comparatively showing P-V curves of an electronic device according to at least one embodiment and an electronic device according to a comparison example.

The electronic device according to at least one embodiment may include a TiN layer, an HZO layer, and an MO layer, and have a structure in which Co is used as a crystalline induction electrode and then removed.

An electronic device according to the comparison example also includes a TiN layer, an HZO layer, and an MO layer, and have a structure in which a crystalline induction electrode is not used.

Referring to remnant polarization (Pr) characteristics of the embodiment and the comparison example, 2Pr is about 23 microcoulombs per centimeter squared (μC/cm²) for the example embodiment and 11 μC/cm² for the comparison example. Thereby, the example embodiment is shown to have remnant polarization characteristics that are about twice (or more) that of the comparison example.

The electronic device according to the comparison example may increase a remnant polarization value through a separate electric wake-up process (e.g., several tens of to several hundreds of times of P-V measurement), while the example embodiment may have high remnant polarization characteristics without such an electric wake-up process.

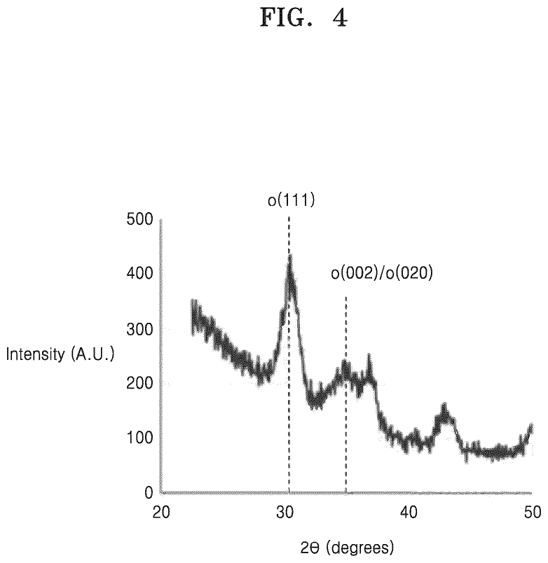

FIG. 4 is an XRD graph of a ferroelectric layer included in an electronic device manufactured by a method according to at least one embodiment.

In the XRD graph, 30.4° and 30.8° corresponding to 2θ peaks respectively indicate peak positions of the orthorhombic phase and the tetragonal phase. Peak positions of a monoclinic phase, 27.5° and 31.6° correspond to peak positions of the monoclinic phase, and in the presence of the monoclinic phase, sub-peaks may be observed at those positions. In the graph of FIG. 4, such monoclinic sub-peaks are not observed; thereby, it may be seen that crystallization is done well.

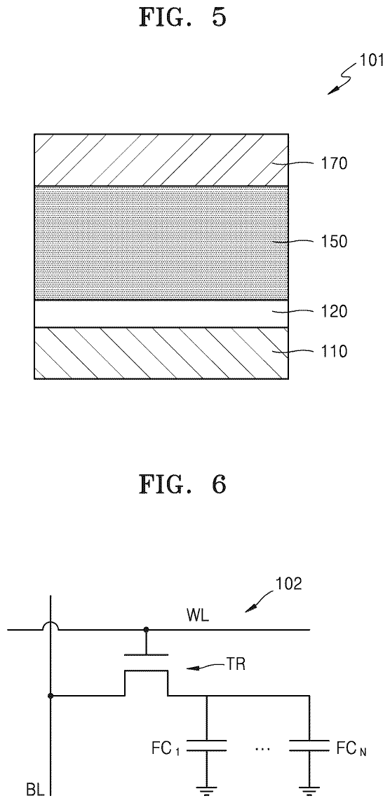

FIG. 5 is a cross-sectional view showing a schematic configuration of an electronic device according to at least one embodiment.

The electronic device 101 is different from the electronic device 100 of FIG. 1 in that the electronic device 101 further includes an interfacial layer 120 between the lower electrode 110 and the ferroelectric layer 150, and the other components of the electronic device 101 are the same as (or substantially similar to) those of the electronic device 100.

The interfacial layer 120 may be a layer for suppressing or preventing electric leakage. The interfacial layer 120 may include a metal oxide including at least one of Hf, Zr, Al, Ti, Ta, and/or Nb. The interfacial layer 120 may include an insulating material including a metal oxide. The interfacial layer 120 may include, for example, HfO_{z}, ZrO_{z}, AlO_{z}, TiO_{z}, TaO_{z}, NbO_{z}, SiO_{z}, LaO_{z}, YO_{z}, or MgO_{z} in which z is a real number greater than 0. The interfacial layer 120 may include an oxide of a material of the lower electrode 110, or a material separate from the lower electrode 110. The interfacial layer 120 may include a plurality of material layers. A thickness of the interfacial layer 120 may be about 1 nm or less. The material, the thickness, etc., of the interfacial layer 120 are not limited thereto. In at least one embodiment, a side of the ferroelectric layer 150 facing the interfacial layer 120 may be opposite to the side on which the crystalline induction electrode 160 was removed.

The above-described electronic device (a ferroelectric capacitor) may be used in various electronic apparatuses. For example, the above-described ferroelectric capacitor may be used in a dynamic random access memory (DRAM) device together with a transistor. The above-described ferroelectric capacitor may also form a part of an electronic circuit constituting the electronic apparatus, together with other circuit elements.

FIG. 6 is a schematic circuit diagram of an electronic device adopting a ferroelectric capacitor, according to embodiments.

An electronic device 102 may include a DRAM device. FIG. 6 shows one cell of a DRAM device in which one cell may include one transistor TR and N ferroelectric capacitors FC₁ and FC_{N}. N may be an integer of at least 1. The ferroelectric capacitors FC₁ and FC_{N} may be the above-described electronic devices 100 and/or 102.

A method to write data on the DRAM device is as below. After a gate voltage (high) that turns the transistor TR into an ‘ON’ state is applied to a gate electrode through the word line WL, a data voltage VDD (high) or 0 (low) to be input to the bit line BL is applied. When the voltage (high) is applied to the word line and the bit line, the ferroelectric capacitors FC₁ and FC_{N} may be charged and data “1” may be recorded, and when the voltage (high) is applied to the word line and a voltage (low) is applied to the bit line, the ferroelectric capacitors FC₁ and FC_{N} may be discharged and data “0” may be recorded.

When data is read, the voltage (high) may be applied to the word line WL to turn ON the transistor TR of the DRAM and then a voltage of VDD/2 may be applied to the bit line BL. When the data of the DRAM device is “1” (e.g., the voltages of the ferroelectric capacitors FC₁ and FC_{N} are VDD) charges in the ferroelectric capacitors FC₁ and FC_{N} slowly move to the bit line BL such that the voltage of the bit line BL may be slightly higher than VDD/2. On the other hand, when the data of the ferroelectric capacitors FC₁ and FC_{N} is “0”, the charges of the bit line BL move to the ferroelectric capacitors FC₁ and FC_{N} such that the voltage of the bit line BL is slightly lower than VDD/2. An electric potential of the bit line, generated in this way, may be sensed and amplified by a sense amplifier, such that whether corresponding data is “0” or “1” may be determined.

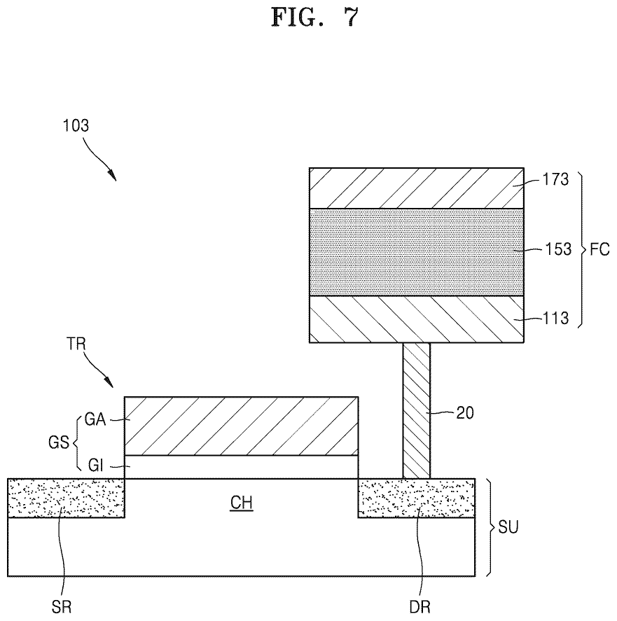

FIG. 7 is a cross-sectional view schematically showing an electronic device 103 according to at least one embodiment.

The shown electronic device 103 may show one cell of a DRAM device. The electronic device 103 may include a transistor TR and a ferroelectric capacitor FC electrically connected thereto. While it is shown in FIG. 7 that the electronic device 103 includes one ferroelectric capacitor FC and one transistor TR, one cell of the electronic device 103 may include one transistor TR and one or more ferroelectric capacitors FC as illustrated in FIG. 6.

The ferroelectric capacitor FC and the transistor TR may be electrically connected to each other by the contact 20. The ferroelectric capacitor FC may include a lower electrode 113, an upper electrode 173, and a ferroelectric layer 153 provided between the lower electrode 113 and the upper electrode 173. The lower electrode 113, the upper electrode 173, and the ferroelectric layer 153 of the ferroelectric capacitor FC may be respectively similar to the lower electrode 110, the upper electrode 170, and the ferroelectric layer 150 of the electronic device 100 or 101 described above. An interfacial layer may be further included between the lower electrode 113 and the ferroelectric layer 153, like the electronic device 101 described with reference to FIG. 5.

The transistor TR may be a field effect transistor. The transistor TR may include a semiconductor substrate SU, which includes a source region SR, a drain region DR, and a channel region CH, and a gate stack GS, which is disposed to face the channel region CH on the semiconductor substrate SU and includes a gate insulating layer GI and a gate electrode GA.

The channel region CH may be a region between the source region SR and the drain region DR and may be electrically connected to the source region SR and the drain region DR. The source region SR may be electrically connected to or contact an end of a side of the channel region CH, and the drain region DR may be electrically connected to or contact an end of the other side of the channel region CH. The channel region CH may be defined as a substrate region between the source region SR and the drain region DR in the semiconductor substrate SU.

The semiconductor substrate SU may include a semiconductor material. The semiconductor substrate SU may include an elemental and/or a compound semiconductor material, for example, silicon (Si), germanium (Ge), silicon germanium (SiGe), silicon carbide (SiC), gallium arsenide (GaAs), indium arsenide (InAs), indium phosphide (InP), etc. The semiconductor substrate SU may include a silicon-on-insulator (SOI) substrate.

The source region SR, the drain region DR, and the channel region CH may be independently formed by injecting impurities to different regions of the semiconductor substrate SU, and in this case, the source region SR, the channel region CH, and the drain region DR may include a substrate material as a base material. The source region SR and the drain region DR may be formed of a conductive material, and in this case, the source region SR and the drain region DR may include, for example, metal, a metal compound, a conductive polymer, etc.

In some embodiments, unlike shown, the channel region CH may be implemented as a separate material layer (thin film). In this case, for example, the channel region CH may include at least one of Si, Ge, SiGe, III-V semiconductors, oxide semiconductors, nitride semiconductors, oxynitride semiconductors, two-dimensional (2D) materials, quantum dots (QD), organic semiconductors, etc. For example, the oxide semiconductors may include InGaZnO, etc., and the 2D materials may include transition metal dichalcogenide (TMD) or graphene, and the QD may include a colloidal QD or a nanocrystal structure.

The gate electrode GA may be separated from the semiconductor substrate SU to oppose the channel region CH on the semiconductor substrate SU. The gate electrode GA may include at least one of metal, a metal nitride, a metal carbide, and polysilicon. For example, the metal may include at least one of aluminum (Al), tungsten (W), molybdenum (Mo), titanium (Ti), and tantalum (Ta), and the metal nitride may include at least one of a titanium nitride (TiN) film and a tantalum nitride (TaN) film. The metal carbide may include at least one of metal carbides doped with (or containing) aluminum and silicon, and detailed examples thereof may include TiAlC, TaAlC, TiSiC, or TaSiC.

The gate electrode GA may have a structure in which a plurality of materials are laminated, for example, a laminated structure of a metal nitride layer/a metal layer such as TiN/Al, etc., or a laminated structure of a metal nitride layer/a metal carbide layer/a metal layer such as TiN/TiAlC/W. However, the aforementioned materials are merely examples.

A gate insulating layer GI may be further arranged between the semiconductor substrate SU and the gate electrode GA. The gate insulating layer GI may include a paraelectric material and/or a high-k dielectric material, and may have a dielectric constant of about 20 to about 70.

The gate insulating layer GI may include, for example, a silicon oxide, a silicon nitride, an aluminum oxide, a hafnium oxide, a zirconium oxide, etc., and/or include a 2D insulator such as a hexagonal boron nitride (h-BN). The gate insulating layer GI may include a silicon oxide (SiO₂), a silicon nitride (SiNₓ), etc., and may include a hafnium oxid₂ (HfO₂), a hafnium silicon oxide (HfSiO₄), a lanthanum oxide (La₂O₃), a lanthanum aluminum oxide (LaAlO₃), a zirconium oxide (ZrO₂), a hafnium zirconium oxide (HfZrO₂), a zirconium silicon oxide (ZrSiO₄), a tantalum oxide (Ta₂O₅) ), a titanium oxide (TiO₂), a strontium titanium oxide (SrTiO₃), a yttrium oxide (Y₂O₃), aluminum oxide (Al₂O₃), a red scandium tantalum oxide (PbSc0.5Ta0.5O₃), red zinc niobate (PbZnNbO₃), etc. The gate insulating layer GI may include a metal nitride oxide such as an aluminum oxynitride (AlON), a zirconium oxynitride (ZrON), a hafnium oxynitride (HfON), a lanthanum oxynitride (LaON), an yttrium oxynitride (YON), etc., a silicate such as ZrSiON, HfSiON, YSiON, LaSiON, etc., or an aluminate such as ZrAlON, HfAlON, etc. The gate insulating layer GI may include the above-described dielectric layers 420, 520, 620, and 720. The gate insulating layer GI may constitute a gate stack together with the gate electrode GA.

One of the electrodes 113 and 173 of the ferroelectric capacitor FC and one of the source region SR and the drain region DR of the transistor TR may be electrically connected to each other, e.g., by a contact 20. The contact 20 may include a conductive material, e.g., tungsten, copper, aluminum, polysilicon, etc.

An arrangement of the ferroelectric capacitor FC and the transistor TR may be changed variously. For example, the ferroelectric capacitor FC may be arranged on the semiconductor substrate SU, or may be buried in the semiconductor substrate SU.

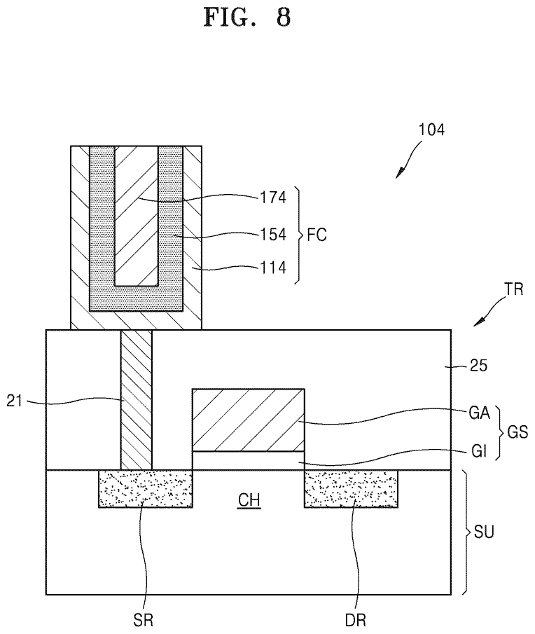

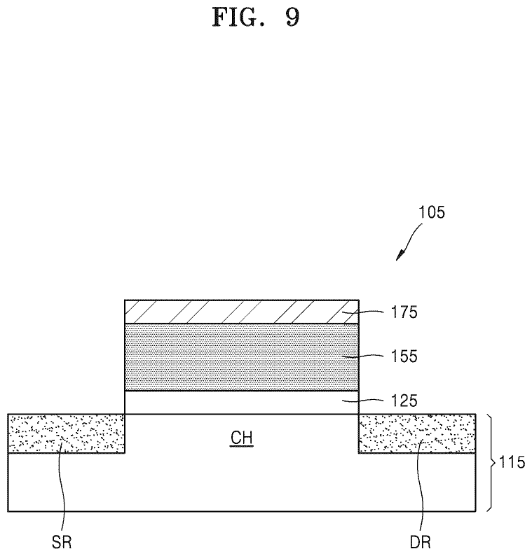

FIG. 8 is a schematic cross-sectional view of an electronic device 104 according to at least one embodiment.

The shown electronic device 104 may show one cell of a DRAM device. The electronic device 104 may include a transistor TR and a ferroelectric capacitor FC electrically connected thereto. While it is shown in FIG. 8 that the electronic device 104 includes one ferroelectric capacitor FC and one transistor TR, one cell of the electronic device 104 may include one transistor TR and one or more ferroelectric capacitors FC as illustrated in FIG. 6.

The transistor TR may include a semiconductor substrate SU, which includes a source region SR, a drain region DR, and a channel region CH, and a gate stack GS, which is disposed to face the channel region CH on the semiconductor substrate SU and includes a gate insulating layer GI and a gate electrode GA.

An interlayer insulating film 25 may be provided to cover the gate stack GS on the semiconductor substrate SU. The interlayer insulating film 25 may include an insulating material. For example, the interlayer insulating film 25 may include Si oxide (e.g., SiO₂), Al oxide (e.g., Al₂O₃), or a high-permittivity material (e.g., HfO₂). The contact 21 may electrically connect the transistor TR to the ferroelectric capacitor FC through the interlayer insulating film 25.

The ferroelectric capacitor FC may include a lower electrode 114, an upper electrode 174, and a ferroelectric layer 154 provided between the lower electrode 114 and the upper electrode 174. The lower electrode 114 and the upper electrode 174 may be provided in a shape to maximize a contact area with the ferroelectric layer 154. Otherwise, the lower electrode 114, the upper electrode 174, and the ferroelectric layer 154 of the ferroelectric capacitor FC may be respectively similar to the lower electrode 110, the upper electrode 170, and the ferroelectric layer 150 of the electronic device 100 or 101 described above. An interfacial layer may be further included between the lower electrode 114 and the ferroelectric layer 154, like the electronic device 101 described with reference to FIG. 5.

FIG. 9 is a schematic cross-sectional view of an electronic device 105 according to at least one embodiment.

The electronic device 105 may include a semiconductor substrate 115, a ferroelectric layer 155, and a gate electrode 175. The semiconductor substrate 115 may include a source region SR, a drain region DR, and a channel region CH. An interfacial layer 125 may be disposed between the channel region CH and the ferroelectric layer 155. The interfacial layer 125 may be an oxide of a material of the channel region CH or may include a separate insulating material. The interfacial layer 125 may be omitted. The foregoing description of the ferroelectric layer 150 of the electronic device 100 or 101 may be applied to the ferroelectric layer 155.

The electronic device 105 may be a field effect transistor. Due to the ferroelectric property of the ferroelectric layer 155, for example, according to a polarization direction in the ferroelectric, a threshold voltage of a field effect transistor may differ. By using such a threshold voltage change characteristics of the ferroelectric field effect transistor, a logic device or a memory device may be implemented. In at least one embodiment, the electronic device 105 may be formed in a similar manner to the method described above, with the gate electrode 175 corresponding to the upper electrode 170.

The electronic devices 100, 101, 102, 103, 104, and 105 described above may be applied as the logic device or the memory device in various electronic apparatuses. The electronic device according to embodiments may respond to the demand for miniaturization and integration of the electronic apparatus. The electronic device according to embodiments may be used for arithmetic operations, program execution, temporary data retaining, etc., in an electronic device such as a mobile device, a computer, a laptop computer, a sensor, a network device, a neuromorphic device, etc. The electronic device according to embodiments may be useful for electronic apparatuses with large data transmission volume and continuous data transmission.

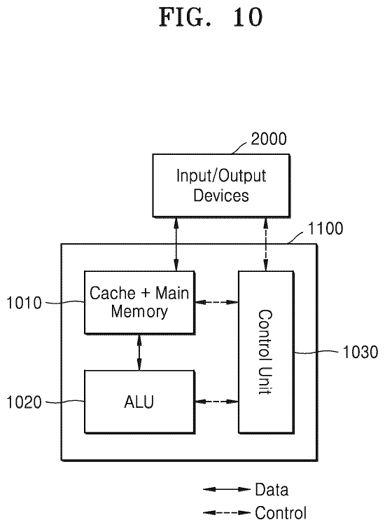

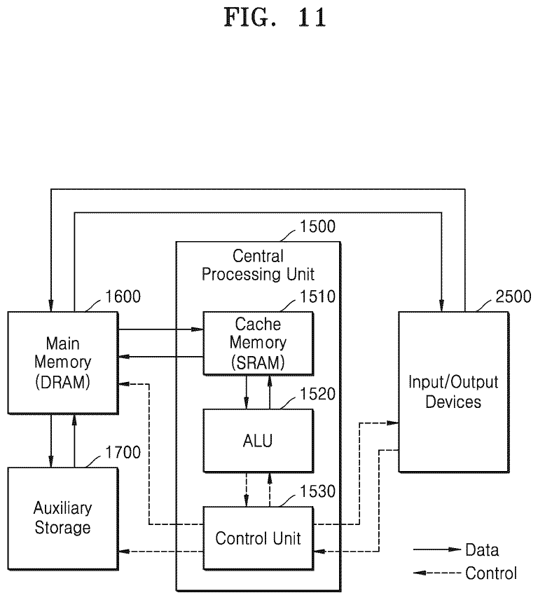

FIGS. 10 and 11 are conceptual views schematically showing a device architecture applicable to an apparatus according to an example embodiment.

Referring to FIG. 10, an electronic device architecture 1000 may include a memory unit 1010, an arithmetic logic unit (ALU) 1020, and a control unit 1030. The memory unit 1010, the ALU 1020, and the control unit 1030 may be electrically connected to one another. For example, the electronic device architecture 1000 may be implemented as one chip including the memory unit 1010, the ALU 1020, and the control unit 1030. More specifically, the memory unit 1010, the ALU 1020, and the control unit 1030 may communicate directly by being connected to one another through a metal line on-chip. The memory unit 1010, the ALU 1020, and the control unit 1030 may be monolithically integrated on one substrate to form one chip. An input/output device 2000 may be connected to the electronic device architecture (chip) 1000. The memory unit 1010 may include both a main memory and a cache memory. The electronic device architecture (chip) 1000 may be an on-chip memory processing unit.

At least one of the memory unit 1010, the ALU 1020, and/or the control unit 1030 may independently include at least one of the electronic devices 100, 101, 102, 103, 104, and 105 described above. The electronic device may be, for example, a logic transistor or a capacitor.

Referring to FIG. 11, a cache memory 1510, an ALU 1520, and a control unit 1530 may constitute a central processing unit (CPU) 1500, and the cache memory 1510 may include a static random access memory (SRAM). The cache memory 1510 may include the above-described electronic device including a ferroelectric. A main memory 1600 and an auxiliary storage 1700 may be included in addition to the CPU 1500, and an input/output device 2500 may also be included. The main memory 1600 may include a dynamic rando access memory (DRAM). The main memory 1600 may include at least one of the electronic devices 100, 101, 102, 103, 104, and 105 described above.

Depending on a circumstance, the electronic device architecture may be implemented in a form where computing-unit devices and memory-unit devices are adjacent to each other in one chip, without distinction of sub-units.

While the above-described electronic device, manufacturing method thereof, and electronic apparatus including the electronic device have been described with reference to the embodiments described in the drawings, it will be understood by those of ordinary skill in the art that various modifications and equivalent other embodiments are possible therefrom. Therefore, the disclosed embodiments should be considered in a descriptive sense rather than a restrictive sense. The scope of the present specification is not described above, but in the claims, and all the differences in a range equivalent thereto should be interpreted as being included.

The above-described electronic device may show high remnant polarization even at small thicknesses.

According to the above-described manufacturing method, the electronic device including a ferroelectric showing a ferroelectric property well even at small thicknesses may be provided.

According to the above-described manufacturing method, a wake-up process for exhibiting the ferroelectric property is not required.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An electronic device comprising:
a lower electrode;
an upper electrode; and
a ferroelectric layer separating the lower electrode and the upper electrode, the ferroelectric layer having a crystalline structure of an orthorhombic phase and comprising
a metal oxide comprising Hf and Zr, and
a metal oxide comprising at least one of Co or Nb.

2. The electronic device of claim 1, wherein the ferroelectric layer further comprises a crystalline structure of a tetragonal phase.

3. The electronic device of claim 1, wherein, in the ferroelectric layer, a content of Hf is greater than a content of Zr.

4. The electronic device of claim 1, wherein a thickness of the ferroelectric layer is at least about 1 nanometer (nm) and about 7 nm or less.

5. The electronic device of claim 1, wherein the upper electrode comprises at least one of TiN, W, Mo, or Ni.

6. The electronic device of claim 1, further comprising:
an interfacial layer between the lower electrode and the ferroelectric layer, the interfacial layer comprising a metal oxide.

7. The electronic device of claim 6, wherein the metal oxide of the interfacial layer comprises at least one of Hf, Zr, Al, Ti, Ta, or Nb.

8. The electronic device of claim 6, wherein a thickness of the interfacial layer is about 1 nanometer (nm) or less.

9. A memory device comprising:
a transistor; and
one or more capacitors electrically connected to the transistor, wherein the one or more capacitors includes the electronic device of claim 1.

10. An electronic device comprising:
a semiconductor substrate;
a gate electrode; and
a ferroelectric layer separating the gate electrode and the semiconductor substrate, the ferroelectric layer comprising a crystalline structure of an orthorhombic phase, and comprising
a metal oxide comprising Hf and Zr, and
a metal oxide comprising at least one of Co or Nb.

11. A method of manufacturing an electronic device, the method comprising:
forming a dielectric layer comprising a metal oxide comprising Hf and Zr;
forming a crystalline induction electrode on the dielectric layer;
forming a ferroelectric layer by annealing the dielectric layer and the crystalline induction electrode such that the metal oxide crystallizes;
removing the crystalline induction electrode; and
forming an upper electrode on the ferroelectric layer.

12. The method of claim 11, wherein the forming the ferroelectric layer comprises forming a crystalline structure of an orthorhombic phase in the metal oxide.

13. The method of claim 11, wherein the crystalline induction electrode comprises at least one of Co, CoN, NbN, or Nb.

14. The method of claim 13, wherein the ferroelectric layer, after removing the crystalline induction electrode, further comprises a metal oxide comprising at least one Co or Nb.

15. The method of claim 11, wherein a temperature during the annealing is about 500 ° C. or less.

16. The method of claim 11, wherein, in the ferroelectric layer, a content of Hf is greater than a content of Zr.

17. The method of claim 11, wherein a thickness of the ferroelectric layer is at least about 1 nanometer (nm) and about 7 nm or less.

18. The method of claim 11, wherein the upper electrode comprises at least one TiN, W, Mo, or Ni.

19. The method of claim 11, wherein the forming the dielectric includes forming the dielectric layer on a lower electrode.

20. The method of claim 11, wherein forming the dielectric includes forming the dielectric layer on a semiconductor substrate.
